(19) United States
(12) Patent Application Publication
(10) Pub. No.: US 2017/0067966 A1
(43) Pub. Date: Mar. 9, 2017

(54) APPARATUS AND METHOD FOR ESTIMATING AVAILABLE POWER OF HIGH VOLTAGE BATTERY

(71) Applicants: Hyundai Motor Company, Seoul (KR); Kia Motors Corporation, Seoul (KR)

(72) Inventor: Kyung In Min, Seongnam (KR)

(21) Appl. No.: 14/943,578

(22) Filed: Nov. 17, 2015

(30) Foreign Application Priority Data
Sep. 8, 2015 (KR) 10-2015-0127091

(51) Int. Cl. G01R 31/36; B60L 11/18

(52) U.S. Cl. CPC G01R 31/3648; B60L 11/1861

(57) ABSTRACT

An apparatus for estimating an available power of a high voltage battery includes: a memory that stores a table recording an available power corresponding to a state of charge (SoC) value of the high voltage battery; a voltage sensor that measures a voltage of the high voltage battery; a current sensor equipped with a first module for measuring a low current of the high voltage battery and a second module for measuring a high current; and a controller that estimates an available power by using the voltage and the low current, or the voltage and the high current, when the voltage sensor is normal, and search an available power corresponding to a SoC value after calculating the SoC value by using the low current or the high current when the voltage sensor is broken.

### CROSS-REFERENCE TO RELATED APPLICATION

This application claims under 35 U.S.C. §119(a) the benefit of Korean Patent Application No. 10-2015-0127091, filed on Sep. 8, 2015 in the Korean Intellectual Property Office, the entire contents of which are incorporated by reference herein.

### BACKGROUND

(a) Technical Field

The present invention relates to an apparatus and method for estimating an available power of a high voltage battery, and more particularly, to an apparatus and method for estimating an available power of a high voltage battery at the time of failure of a current sensor or a voltage sensor, in an eco-friendly vehicle that calculates the available power of the high voltage battery based on the current sensor equipped with a low current measurement module and a high current measurement module and the voltage sensor.

(b) Description of the Related Art

An eco-friendly vehicle refers to a vehicle driven by operating an electric motor using a high voltage battery, and includes a Hybrid Electric Vehicle (HEV), an Electric Vehicle (EV), a Plug-in Hybrid Electric Vehicle (PHEV), a Fuel Cell Electric Vehicle (FCEV), and the like.

A conventional apparatus for estimating an available power of a high voltage battery is equipped with a voltage sensor to measure a voltage of the high voltage battery and a current sensor to measure a current to estimate an available power of the high voltage battery.

When any one of the voltage sensor or the current sensor is broken (i.e., the sensor cannot measure the voltage or current), the conventional apparatus for estimating the available power of the high voltage battery reduces a certain amount of available power calculated immediately before the sensor is broken (i.e., when both the voltage sensor and the current sensor are normal) to estimate the available power, while monitoring a measured value of a sensor in which failure does not occur. In particular, when the voltage sensor is broken, the apparatus for estimating an available power transmits data indicating the failure of the voltage sensor to a controller area network (CAN); and when the current sensor is broken, transmits data indicating the failure of the current sensor to the controller area network (CAN).

In addition, when both the voltage sensor and the current sensor are broken, the conventional apparatus for estimating the available power of the high voltage battery blocks a relay so as to protect the high voltage battery, and disables the high voltage battery so as to prevent use. In such a situation, the eco-friendly vehicle is shut-down.

In recent years, an eco-friendly vehicle that calculates an available power of a high voltage battery based on a current sensor equipped with a low current measurement module and a high current measurement module and a voltage sensor has been developed.

A method of estimating the available power of the high voltage battery when the current sensor or the voltage sensor is broken in such an eco-friendly vehicle is required.

### SUMMARY

The present invention provides an apparatus for estimating an available power of a high voltage battery which can prevent a shutdown of a vehicle during driving of the vehicle to ensure safety of occupant(s), by estimating the available power of the high voltage battery at the time of failure of a current sensor or a voltage sensor, in particular, in an eco-friendly vehicle that calculates the available power of the high voltage battery based on the current sensor equipped with a low current measurement module and a high current measurement module and the voltage sensor, and a method thereof.

In accordance with an aspect of the present invention, an apparatus for estimating an available power of a high voltage battery includes: a memory configured to store a table recording the available power corresponding to a state of charge (SoC) value of the high voltage battery; a voltage sensor configured to measure a voltage of the high voltage battery; a current sensor equipped with a first module for measuring a low current of the high voltage battery and a second module for measuring a high current; and a controller configured to estimate the available power by using the voltage and the low current or the voltage and the high current when the voltage sensor is normal, and search an available power corresponding to the SoC value after calculating the SoC value by using the low current or the high current when the voltage sensor is broken.

In accordance with another aspect of the present invention, a method for estimating an available power of a high voltage battery based on a current sensor equipped with a low current measurement module and a high current measurement module and a voltage sensor includes: storing a table recording the available power corresponding to a state of charge (SoC) value of the high voltage battery by a memory; estimating an available power by using the voltage and the low current or the voltage and the high current, when the voltage sensor is normal; calculating the SoC value by using the low current or the high current, when the voltage sensor is broken; and searching the available power corresponding to the calculated SoC value from the memory.

### BRIEF DESCRIPTION OF THE DRAWINGS

The objects, features and advantages of the present invention will be more apparent from the following detailed description in conjunction with the accompanying drawings, in which:

FIG. 1 is a block diagram illustrating a configuration of an apparatus for estimating an available power of a high voltage battery according to an embodiment of the present invention; and

FIG. 2 is a flowchart illustrating a method for estimating the available power of the high voltage battery according to the embodiment of the present invention.

### DETAILED DESCRIPTION OF EXEMPLARY EMBODIMENTS

It is understood that the term “vehicle” or “vehicular” or other similar term as used herein is inclusive of motor vehicles in general such as passenger automobiles including sports utility vehicles (SUV), buses, trucks, various commercial vehicles, watercraft including a variety of boats and ships, aircraft, and the like, and includes hybrid vehicles, electric vehicles, plug-in hybrid electric vehicles, hydrogen-powered vehicles and other alternative fuel vehicles (e.g. fuels derived from resources other than petroleum). As referred to herein, a hybrid vehicle is a vehicle that has two or more sources of power, for example both gasoline-powered and electric-powered vehicles.

The terminology used herein is for the purpose of describing particular embodiments only and is not intended to be limiting of the invention. As used herein, the singular forms “a,” “an” and the are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof. As used herein, the term “and/or” includes any and all combinations of one or more of the associated listed items. Throughout the specification, unless explicitly described to the contrary, the word “comprise” and variations such as “comprises” or “comprising” will be understood to imply the inclusion of stated elements but not the exclusion of any other elements. In addition, the terms “unit”, “-er”, “-or”, and “module” described in the specification mean units for processing at least one function and operation, and can be implemented by hardware components or software components and combinations thereof.

Further, the control logic of the present invention may be embodied as non-transitory computer readable media on a computer readable medium containing executable program instructions executed by a processor, controller or the like. Examples of computer readable media include, but are not limited to, ROM, RAM, compact disc (CD)-ROMs, magnetic tapes, floppy disks, flash drives, smart cards and optical data storage devices. The computer readable medium can also be distributed in network coupled computer systems so that the computer readable media is stored and executed in a distributed fashion, e.g., by a telematics server or a Controller Area Network (CAN).

Exemplary embodiments of the present invention are described with reference to the accompanying drawings in detail. The same reference numbers are used throughout the drawings to refer to the same or like parts. Detailed descriptions of well-known functions and structures incorporated herein may be omitted to avoid obscuring the subject matter of the present invention.

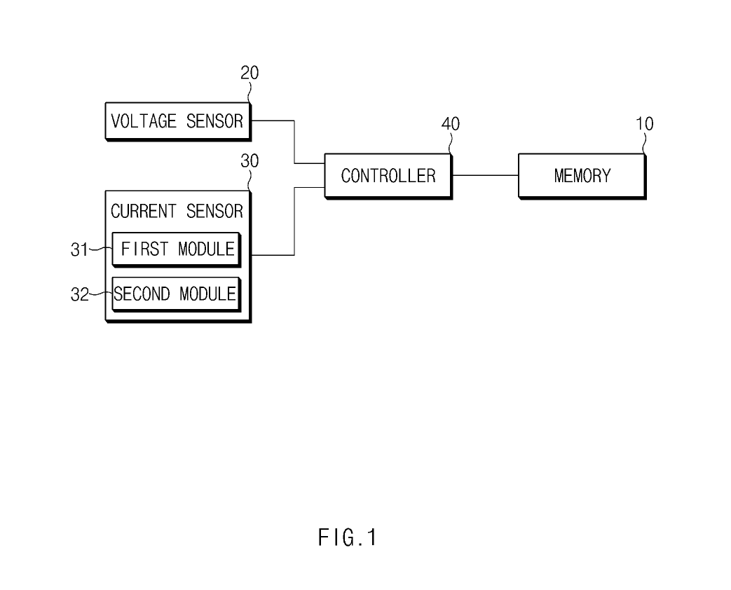

FIG. 1 is a block diagram illustrating a configuration of an apparatus for estimating an available power of a high voltage battery according to an embodiment of the present invention.

As shown in FIG. 1, the apparatus for estimating the available power of the high voltage battery according to the embodiment of the present invention may include a memory 10, a voltage sensor 20, a current sensor 30, and a controller 40.

Referring to each element, the memory 10 may store a table recording an available power corresponding to a state of charge (SoC) value of the high voltage battery. A unit of the SoC value is percentage (%).

Next, the voltage sensor 20 may measure a voltage of the high voltage battery. However, the voltage sensor 20 may be unable to measure the voltage in case of failure and thus cannot transmit a voltage value to the controller 40.

Next, the current sensor 30 may measure a current of the high voltage battery. In particular, the current sensor 30 may be provided with a first module 31 for measuring a low current and a second module 32 for measuring a high current. Here, a measurement range of the first module 31 may be, e.g., ±30 A, and a measurement range of the second module 32 may be, e.g., ±350 A.

In particular, the current sensor 30 cannot measure the low current when a failure occurs in the first module 31, and cannot measure the high current when a failure occurs in the second module 32.

Next, the controller 40 may perform an overall control so that the above respective elements may normally perform their own functions.

A process of estimating an available power of the high voltage battery by the controller 40 when a failure occurs in the voltage sensor 20 and the current sensor 30 is as follows.

When the voltage sensor 20 is normal, and when the first module 31 of the current sensor 30 is broken, then the available power is estimated by using a voltage value measured by the voltage sensor 20 and a current value measured by the second module 32.

When the voltage sensor 20 is normal, and when the second module 32 of the current sensor 30 is broken, then the available power is estimated by using a voltage value measured by the voltage sensor 20 and a current value measured by the first module 31

When the voltage sensor 20 is normal, and when the first module 31 and the second module 32 of the current sensor 30 are broken, then the available power is estimated by decreasing the available power calculated immediately before the voltage sensor 20 and first or second module 31, 32 are broken (i.e., when both the voltage sensor and the current sensor are normal), while monitoring a voltage value measured by the voltage sensor 20.

When the voltage sensor 20 is broken, and when the first module 31 of the current sensor 30 is broken, then a SOC value is calculated using a high current measured by the second module 32, and the available power corresponding to the calculated SoC value is searched from a table stored in the memory 10. The searched available power is estimated as the available power.

When the voltage sensor 20 is broken, and when the second module 32 of the current sensor 30 is broken, then the controller 40 calculates a SOC value using a low current measured by the first module 31, and searches the available power corresponding to the calculated SoC value from a table stored in the memory 10. The searched available power is estimated as the available power.

When the voltage sensor 20 is broken, and when the first module 31 and the second module 32 of the current sensor 30 are broken, then a relay is turned off so as not to use a high voltage battery.

In summary, based on the voltage sensor 20, when a failure does not occur in the voltage sensor 20, an available power may be estimated based on the voltage measured by the voltage sensor 20 and the current measured by a module which is not broken between the first module 31 and the second module 32. However, when all of the voltage sensor 20, the first module 31, and the second module 32 are broken, the use of the high voltage battery may be prevented.

On the other hand, when a failure occurs in the voltage sensor 20, and when any one module of the first module 31 and the second module 32 is broken, the SoC may be calculated by using the current measured by the module which is not broken, and a corresponding available power may be read from the memory 10.

As a result, when the voltage sensor 20 is not broken, the available power may be estimated, and when the voltage sensor 20 is broken, the available power may be read from the memory 10. However, when both the first module 31 and the second module 32 are broken while the voltage sensor 20 is not broken, the available power which is calculated immediately before in a conventional manner may be decreased to a certain extent and estimated as a current available power. Further, when all of the voltage sensor 20, the first module 31, and the second module 32 are broken, the use of the high voltage battery may be prevented. As a result, the connection of the high voltage battery and the load may be blocked.

The present invention may efficiently estimate the available power of the high voltage battery when the current sensor or the voltage sensor is broken, in an eco-friendly vehicle that calculates an available power of the high voltage battery based on the current sensor equipped with a low current measurement module and a high current measurement module and the voltage sensor.

On the other hand, in the present invention, the technology of calculating the SoC value utilizes a well-known current integration method. The current integration method is also known as Coulomb counting, and measures the current of the battery and integrates the measured current with respect to time to calculate the SoC value.

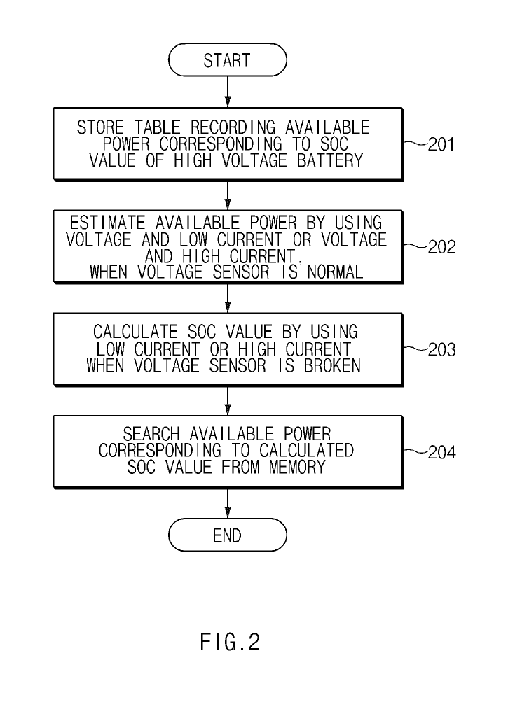

FIG. 2 is a flowchart illustrating a method for estimating the available power of a high voltage battery according to the embodiment of the present invention, and shows a process of estimating the available power of the high voltage battery based on the current sensor 30 equipped with a low current measurement module and a high current measurement module and the voltage sensor 20.

First, the memory 10 may store a table recording an available power corresponding to a state of charge (SoC) value of the high voltage battery (step 201).

Then, when the voltage sensor 20 is normal, the controller 40 may estimate the available power by using a voltage measured by the voltage sensor 20 and a low current measured by the low current measurement module or a voltage measured by the voltage sensor 20 and a high current measured by the high current measurement module (step 202).

Then, when the voltage sensor 20 is broken, the controller 40 may calculate the SoC value by using the low current measured by the low current measurement module or the high current measured by the high current measurement module (step 203).

Then, the controller 40 may search the available power corresponding to the calculated SoC value from the memory 10 (step 204). The searched available power may be estimated as a current available power.

As described above, the present invention can prevent a shutdown of a vehicle during driving of the vehicle to ensure a safety of occupant(s), by estimating an available power of a high voltage battery at the time of the failure of a current sensor or a voltage sensor, in an eco-friendly vehicle that calculates an available power of the high voltage battery based on the current sensor equipped with a low current measurement module and a high current measurement module and the voltage sensor.

The foregoing method of the present invention may be implemented in a program command form executable by various computer means and be recorded in a computer readable recording medium. In this case, the computer readable recording medium may include a program command, a data file, and a data structure individually or a combination thereof. Further, the program command includes a machine language code created by a compiler and a high-level language code executable by a computer using an interpreter. The foregoing hardware device may be configured to be operated according to at least one software module to perform an operation of the present invention, or software modules may be configured to be operated according to the hardware device.

Although exemplary embodiments of the present invention have been described in detail hereinabove, it should be clearly understood that many variations and modifications of the basic inventive concepts herein taught which may appear to those skilled in the present art will still fall within the spirit and scope of the present invention, as defined in the appended claims.

What is claimed is:

1. An apparatus for estimating an available power of a high voltage battery, the apparatus comprising:
a memory configured to store a table recording the available power corresponding to a state of charge (SoC) value of the high voltage battery;
a voltage sensor configured to measure a voltage of the high voltage battery;
a current sensor equipped with a first module for measuring a low current of the high voltage battery and a second module for measuring a high current; and
a controller configured to estimate the available power by using the voltage and the low current or the voltage and the high current when the voltage sensor is normal, and search an available power corresponding to the SoC value after calculating the SoC value by using the low current or the high current when the voltage sensor is broken.

2. The apparatus of claim 1, wherein the controller estimates the available power by using the voltage and the high current, when the voltage sensor is normal and the first module is broken.

3. The apparatus of claim 1, wherein the controller estimates the available power by using the voltage and the low current, when the voltage sensor is normal and the second module is broken.

4. The apparatus of claim 1, wherein the controller calculates the SoC value by using the high current, when the voltage sensor is broken and the first module is broken.

5. The apparatus of claim 1, wherein the controller calculates the SoC value by using the low current, when the voltage sensor is broken and the second module is broken.

6. A method for estimating an available power of a high voltage battery based on a current sensor equipped with a low current measurement module and a high current measurement module and a voltage sensor, the method comprising the steps of:
storing a table recording the available power corresponding to a state of charge (SoC) value of the high voltage battery by a memory;
estimating an available power by using the voltage and the low current or the voltage and the high current, when the voltage sensor is normal;
calculating the SoC value by using the low current or the high current, when the voltage sensor is broken; and
searching an available power corresponding to the calculated SoC value from the memory.

7. The method of claim 6, wherein the step of estimating the available power comprises estimating the available power by using the voltage and the high current, when the voltage sensor is normal and the low current measurement module is broken.

8. The method of claim 6, wherein the step of estimating the available power comprises estimating the available power by using the voltage and the low current, when the voltage sensor is normal and the high current measurement module is broken.

9. The method of claim 6, wherein the step of calculating the SoC value comprises calculating the SoC value by using the high current, when the voltage sensor is broken and the low current measurement module is broken.

10. The method of claim 6, wherein the step of calculating the SoC value comprises calculating the SoC value by using the low current, when the voltage sensor is broken and the high current measurement module is broken.
